(19) United States
(12) Patent Application Publication
(10) Pub. No.: US 2003/0189448 A1
(43) Pub. Date: Oct. 9, 2003

(54) MOSFET inverter with controlled slopes and a method of making

(75) Inventor: Christian Boemler, Cortland, NY (US)

Correspondence Address: Bernhard P. Molldrem, Jr., 333 East Onondaga Street, Syracuse, NY, 13202, US

(73) Assignee: Silicon Video, Inc.

(21) Appl. No.: 10/409,323

(22) Filed: Apr. 8, 2003

Related U.S. Application Data
(60) Provisional application No. 60/370,935, filed on Apr. 8, 2002.

(51) Int. Cl. H03B 1/00

(52) U.S. Cl. 327/112

(57) ABSTRACT

An inverter is implemented in cascode having a first and second NFET and a PFET. The first NFET is biased with a voltage that makes a nearly constant and limited drain-source voltage V_{DS} across the second lower NFET providing a current limiting effect. When an inverter input thereof goes low the PFET will pull the output high normally and the lower NFET is turned off normally. When the inverter input goes high with a normally fast edge, the PFET turns off and the lower NFET pulls the output down. Because of the cascode configuration, the inverter of this embodiment will be current limited and source-drain current is controllable by the bias current. Therefore, a slow and controllable falling edge is produced by this simple circuit. That is, changing the bias voltage applied to the bias terminal changes the slope of the trailing or falling edge of the output waveform. A four transistor implementation and a complementary implementation are possible.

### FIELD OF THE INVENTION

The present invention relates generally to inverters and, more particularly, to a MOSFET inverter with controlled slopes for delay and charge injection minimizing.

### BACKGROUND OF THE INVENTION

Charge injection in sample and hold amplifiers and other analog transmission gate circuits are a major concern for analog circuits where accuracy is critical and wide variations in supply voltage operating ranges are common. A known way of reducing charge injection is to slow down the edges of the logic control signal to the transmission gates. In the case where one of the transmission gate connections is low impedance or is regulated, slowly turning off the transmission gate will cause the low impedance node to consume all the charge injection from either the rail voltage or the threshold voltage Vt of the lower impedance node, and prevent that charge from influencing the high impedance node.

If an NFET is used as a transmission gate, the charge injection that results from turning off the FET quickly will rise or fall in proportion to the product of the supply voltage times the channel capacity—whereas if the FET is turned off slowly, the charge injection will be a product of the sum of node threshold voltage Vt plus node voltage times the channel capacity. Modern equipment (and battery-operated equipment in particular) is required to be able to operate over a wide operating voltage range, and because of the resulting variances in operating voltage, it is a priority to remove the supply voltage from the charge injection equation. Making the charge injection independent of supply voltage provides a huge advantage, and can reduce overall power consumption as well.

The fall time of the controlling signal should be slow enough that the low impedance node will be able to consume the majority of the charge injection. This requirement then demands there be some way to control the fall time for each of the different sub-circuits with each given analog transmission gate.

Typically, the need for a delay line arises in many digital designs. The delay line is usually implemented by a long string of normal inverters with some additional capacitive load to slow down the leading and trailing edges. The additional capacitive load will cause the inverter to draw more charge from the power supply when the output levels change, and that can generate noise in both the substrate and the supply lines. This resulting noise is unwanted in sensitive analog circuits, and should be avoided where possible.

Previously, circuitry for creating a slow falling or slow rising edge was implemented using resistitive pull-ups or pull-downs on the inverter output or on an open drain inverter. Such design has a significant current draw when the inverter is in steady-state, as opposed to a regular inverter configuration that only draws current during input signal transitions. Another problem arises in that the required resistors are bulky, creating problems in circuit design and layout.

### BRIEF DESCRIPTION OF THE DRAWINGS

FIG. 1 is a circuit diagram of a MOSFET inverter in accordance with one embodiment of the present invention;

FIG. 2 is a circuit diagram of a MOSFET inverter in accordance with another embodiment of the present invention; and

FIG. 3 is a circuit diagram of a MOSFET inverter in accordance with yet another embodiment of the present invention.

### DETAILED DESCRIPTION

The analog cascode coupling principle in accordance with embodiments of the present invention is used for digital inverters as shown in the Drawing and as disclosed in respect to the embodiments described here.

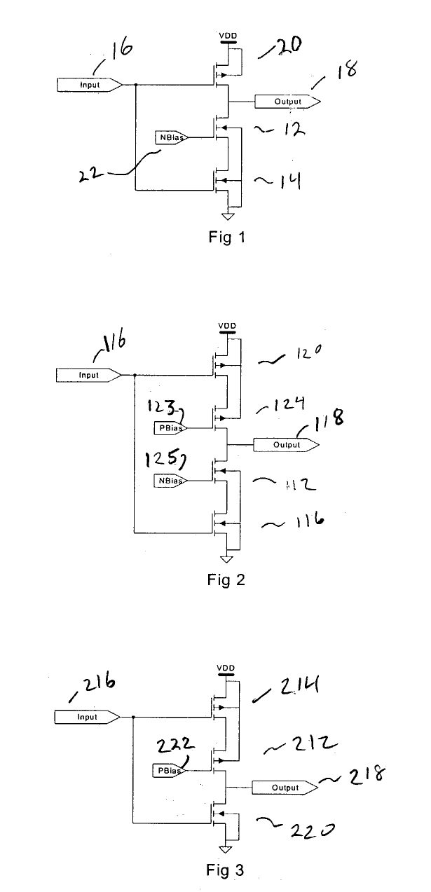

With reference to the Drawing, and initially to FIG. 1, one embodiment of an inverter according to this intention employs a the center NFET 12, and a second, lower NFET 14, as well as an inverter input terminal 14 and an output terminal 16. In addition a PFET 20 is coupled with in series with the NFETs 12 and 14. The NFET 12 has its gate coupled to a bias terminal 22, and is biased with a voltage that makes a nearly constant and limited drain-source voltage V_{DS} across a lower NFET 14 and thus provides a current limiting effect on that device. When an inverter input 16 thereof goes low (and a voltage at an output 18 thereof goes high) the PFET 20 will pull the output 18 high normally and the lower NFET 14 is turned off normally. When the inverter input 16 goes high with a normally fast edge, the PFET 20 turns off and the lower NFET 14 pulls down the output node. Also shown here are a source of drain voltage V_{DD}, and a common terminal or ground. Because of the cascode configuration, the inverter of this embodiment will be current limited and source-drain current is controllable by the bias current. Therefore, a slow and controllable falling edge is produced by this simple circuit. That is, changing the bias voltage applied to the bias terminal 22 changes the slope of the trailing or falling edge of the output waveform.

Another advantage of this design is that it draws no current in steady-state operation and the charge used for charging and discharging the capacitive load is identical to the charge used with a normal inverter.

This inverter can also be implemented with a cascoded PFET with a different bias voltage to produce a slow rising edge of the inverter output.

Also, a four transistor embodiment that uses both PFET and NFET cascodes can be implemented as shown in FIG. 2. With this embodiment it is possible to generate a slow falling and rising edge output. In this embodiment, there are PFETs 120 and 124, and NFETs 112 and 114, with positive bias 123 being applied to PFET 124 and negative bias 125 to NFET 112. The output 118 is joined to the source of PFET 124 and the drain of NFET 112.

A complementary embodiment using a cascoded PFET inverter is shown in FIG. 3. Here, there are first and second PFETs 212 and 214, and an NFET 220, with an input 216 and an output 218 between source and drain of the transistors 212 and 220. A bias voltage applied to bias input 222 produces a slow rising edge on the output waveform, and the bias voltage here is controlled to change the slope of the leading or rising edge.

The present invention is also applicable for delay lines, where a bit (or clock signal) needs to be delayed by some necessary amount of time. By using the slow falling and rising edge inverter of this invention, of the conventional string of inverters with additional capacitive load, longer delay times can be achieved using much less space and while generating significantly less switching noise.

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and scope of the invention. Additionally, the recited order of processing elements or sequences, or the use of numbers, letters, or other designations therefor, is not intended to limit the claimed processes to any order except as may be specified in the claims.

I claim:

1. An inverter comprising:
A bias terminal; an input terminal; an output terminal; a drain power supply; and a common terminal;
a first NFET with a gate, a source, and a drain, the gate of the first NFET being coupled to a bias input for the inverter;
a second NFET with a gate, a source, and a drain, the drain of the second NFET being coupled to the source of the first NFET and the source of the second NFET being coupled to said common terminal; and
a PFET with a gate, a source, and a drain, the gate of the PFET being coupled to the gate of the second NFET and to said input of the inverter, the source of the PFET is coupled to a first power source, and the drain of the PFET is coupled to the source of the first NFET and to said output for the inverter:

2. An inverter comprising:
A first bias terminal; a second bias terminal; an input terminal; an output terminal; a drain power supply; and a common terminal;
a first PFET with a gate, a source, and a drain, the gate of the first PFET being coupled to said first bias input and the drain of the first PFET being coupled to said output for the inverter;
a second PFET with a gate, a source, and a drain, the gate of the second PFET being coupled to said input of the inverter, the source of the second PFET being coupled to a drain power supply, the drain of the second PFET being coupled to the source of the first PFET;
a first NFET with a gate, a source, and a drain, the gate of the first NFET being coupled to said second bias input and the drain of the first NFET being coupled to the drain of the first PFET and to the output of the inverter; and
a second NFET with a gate, a source, and a drain, the gate of the second NFET being coupled to the input for the inverter, the drain of the second NFET being coupled to the source of the first NFET, and the source of the second NFET is coupled to said common terminal.

3. An inverter comprising:
A bias terminal; an input terminal; an output terminal; a source power supply; and a common terminal;
a first PFET with a gate, a source, and a drain, the gate of the first PFET being coupled to said bias input for the inverter;
a second PFET with a gate, a source, and a drain, the drain of the second PFET being coupled to the source of the first PFET and the source of the second PFET being connected to said source power supply; and
an NFET with a gate, a source, and a drain, the gate of the NFET is coupled to the gate of the second PFET and to an input to the inverter, the source of the NFET is coupled to ground and the drain is connected to the source of the first PFET and an output for the inverter.
